(19) United States
(12) Patent Application Publication
(10) Pub. No.: US 2017/0365518 A1
(43) Pub. Date: Dec. 21, 2017

(54) SEMICONDUCTOR PACKAGES WITH SUB-TERMINALS AND RELATED METHODS

(71) Applicant: SEMICONDUCTOR COMPONENTS INDUSTRIES, LLC, Phoenix, AZ (US)

(72) Inventors: Atapol Prajuckamol, Klaeng (TH); Chee Hiong Chew, Seremban (MY); Azhar Aripin, Subang Jaya (MY)

(73) Assignee: SEMICONDUCTOR COMPONENTS INDUSTRIES, LLC, Phoenix, AZ (US)

(21) Appl. No.: 15/696,800

(22) Filed: Sep. 6, 2017

Related U.S. Application Data
(62) Division of application No. 14/624,893, filed on Feb. 18, 2015.

(51) Int. Cl. H01L 21/78; H01L 23/24; H01L 21/54; H01L 23/00; H01L 23/049; H01L 23/498; H01L 25/065; H01L 25/07

(52) U.S. Cl. CPC H01L 21/78; H01L 23/049; H01L 23/24; H01L 23/49811; H01L 21/54; H01L 24/97; H01L 2225/1023; H01L 2224/97; H01L 2224/92247; H01L 2224/92246; H01L 2224/84; H01L 2224/73265; H01L 2224/73263; H01L 2224/48227; H01L 2224/48137; H01L 2224/48091; H01L 2224/40227; H01L 2224/40137; H01L 2224/32225; H01L 2224/16227; H01L 2224/06181; H01L 2224/04042; H01L 2224/04034; H01L 2224/0401; H01L 25/072; H01L 25/0655; H01L 24/92; H01L 24/73; H01L 24/48; H01L 24/40; H01L 24/32; H01L 24/16; H01L 24/06; H01L 2225/1058; H01L 2924/13055; H01L 2924/13091; H01L 2924/15192; H01L 2924/181; H01L 2924/15322

(57) ABSTRACT

A semiconductor device package includes a substrate having first and second opposing surfaces. A first surface of a die couples to the second surface of the substrate, and a first surface of an electrically conductive sub-terminal electrically couples with an electrical contact of the die and physically couples to the second surface of the substrate. A mold compound encapsulates the die and a majority of the sub-terminal. In implementations a first surface of the mold compound is coupled to the second surface of the substrate and a second surface of the mold compound opposing the first surface of the mold compound is flush with a second surface of the sub-terminal opposing the first surface of the sub-terminal. In implementations the sub-terminal includes a pillar having a longest length perpendicular to a longest length of the substrate. In implementations an electrically conductive pin couples to the second surface of the sub-terminal.

### CROSS REFERENCE TO RELATED APPLICATIONS

This application is a divisional application of the earlier U.S. Utility patent application to Prajuckamol et al. entitled “Semiconductor Packages With Sub-Terminals and Related Methods,” application Ser. No. 14/624,893, filed Feb. 18, 2015, now pending, the disclosure of which is hereby incorporated entirely herein by reference.

### BACKGROUND

### 1. Technical Field

Aspects of this document relate generally to semiconductor device packaging.

### 2. Background Art

Semiconductor devices are often encased within (or partly within) a package prior to use. Some packages contain a single die while others contain multiple die. The package often offers some protection to the die, such as from corrosion, impact and other damage, and often also includes electrical leads or other components which connect the electrical contacts of the die with a motherboard or other component either directly or via a socket or other coupling element. The package may also include components configured to dissipate heat from the die into a motherboard or otherwise away from the package.

### SUMMARY

Implementations of semiconductor device packages may include: a substrate having a first surface and a second surface on an opposing side of the substrate from the first surface; a die coupled to the second surface of the substrate at a first surface of the die; an electrically conductive sub-terminal electrically coupled with an electrical contact of the die and physically coupled to the second surface of the substrate at a first surface of the sub-terminal, the sub-terminal having a second surface on an opposing side of the sub-terminal from the first surface of the sub-terminal; and a mold compound that encapsulates the die and a majority of the sub-terminal.

Implementations of semiconductor device packages may include one, all, or any of the following: the mold compound may be coupled to the second surface of the substrate at a first surface of the mold compound and a second surface of the mold compound opposing the first surface of the mold compound may be flush with the second surface of the sub-terminal.

The sub-terminal may include a pillar having a longest length that is perpendicular to a longest length of the substrate.

An electrically conductive pin may be coupled to the sub-terminal at the second surface of the sub-terminal.

The pin may be either soldered to the sub-terminal or press-fit into a cavity of the sub-terminal.

A polymer case may be attached to either or both of the mold compound and the substrate and may include an opening through which the pin extends.

A polymer case may be fixedly attached to, and may partially encase, the pin.

A polymer case may be attached to either or both of the mold compound and the substrate, the polymer case coupled to a base plate and the base plate coupled to the substrate at the first surface of the substrate.

The mold compound may not include silicone.

Implementations of methods of forming a semiconductor package may include: coupling each first surface of a plurality of die with a second surface of a substrate, the substrate having a first surface on a side of the substrate opposing the second surface of the substrate, each die having a second surface on an opposing side of the die from the first surface of the die; coupling each first surface of a plurality of electrically conductive sub-terminals to the second surface of the substrate, each sub-terminal having a second surface on an opposing side of the sub-terminal from the first surface of the sub-terminal; encapsulating each die and a majority of each sub-terminal in a mold compound to form a plurality of coupled semiconductor packages; and singulating the plurality of coupled semiconductor packages to form a plurality of singulated semiconductor packages.

Implementations of methods of forming a semiconductor package may include one, all, or any of the following:

The mold compound may be coupled to the second surface of the substrate at a first surface of the mold compound, and a second surface of the mold compound, on an opposing side of the mold compound from the first surface of the mold compound, may be flush with the second surface of each sub-terminal.

Each sub-terminal may be electrically coupled, through an electrical connector, with an electrical contact of one of the die, the electrical contact located on either the first surface of the die or the second surface of the die.

Each sub-terminal may include a pillar and each pillar may have a longest length that is perpendicular to a longest length of the substrate.

A pin may be coupled to one of the sub-terminals through soldering or a friction fit.

Encapsulating each die and a majority of each sub-terminal in the mold compound may include resin transfer molding and the mold compound may not include silicone.

Implementations of methods of forming a semiconductor package may include: coupling a plurality of die with a substrate, each die coupled to the substrate at a first surface of the die and at a second surface of the substrate, the substrate having a first surface on a side of the substrate opposing the second surface of the substrate, each die having a second surface on an opposing side of the die from the first surface of the die; coupling each first surface of a plurality of conductive pillars to the second surface of the substrate, each conductive pillar electrically coupled with one of the die, each conductive pillar having a second surface on a side of the conductive pillar opposing the first surface of the conductive pillar; encapsulating each of the die and a portion of each conductive pillar in a mold compound, forming a plurality of coupled semiconductor packages, singulating the plurality of coupled semiconductor packages to form a plurality of singulated semiconductor packages; and coupling a pin to one of the conductive pillars.

Implementations of methods of forming a semiconductor package may include one, all, or any of the following:

The pin may be coupled to one of the singulated semiconductor packages and a longest length of the pin may be substantially perpendicular to a longest length of the singulated semiconductor package to which the pin is coupled.

The mold compound may be coupled to the second surface of the substrate at a first surface of the mold compound and a second surface of the mold compound, on an opposing side of the mold compound from the first surface of the mold compound, may be flush with the second surface of each conductive pillar.

Encapsulating each of the die and a portion of each conductive pillar in a mold compound may include resin transfer molding and the mold compound may not include silicone.

Each conductive pillar may be electrically coupled, through an electrical connector, with an electrical contact of one of the die, the electrical contact located on one of the first surface of the die and the second surface of the die.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross-section view of elements used in an implementation of a method of forming the semiconductor package of FIG. 3;

FIG. 2 is a cross-section view of elements used in an implementation of a method of forming the semiconductor package of FIG. 3;

FIG. 3 is a cross-section view of an implementation of a semiconductor package;

FIG. 4 is a cross-section view of a power module including the semiconductor package of FIG. 3 with additional packaging elements;

FIG. 5 is a cross-section view of a power module including the semiconductor package of FIG. 3 with additional packaging elements;

FIG. 6 is a cross-section view of a power module including the semiconductor package of FIG. 3 with additional packaging elements;

FIG. 7 is a cross-section view of a pin soldered to a sub-terminal of an implementation of a semiconductor device package;

FIG. 8 is a cross section view of a press-fit pin pressed into a cavity of a sub-terminal of an implementation of a semiconductor device package;

FIG. 9 is a perspective view of the power module of FIG. 5, and;

FIG. 10 is a perspective view of the power module of FIG. 6.

### DESCRIPTION

This disclosure, its aspects and implementations, are not limited to the specific components, assembly procedures or method elements disclosed herein. Many additional components, assembly procedures and/or method elements known in the art consistent with the intended semiconductor packages with sub-terminals and related methods will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such semiconductor packages with sub-terminals and related methods and implementing components and methods, consistent with the intended operation and methods.

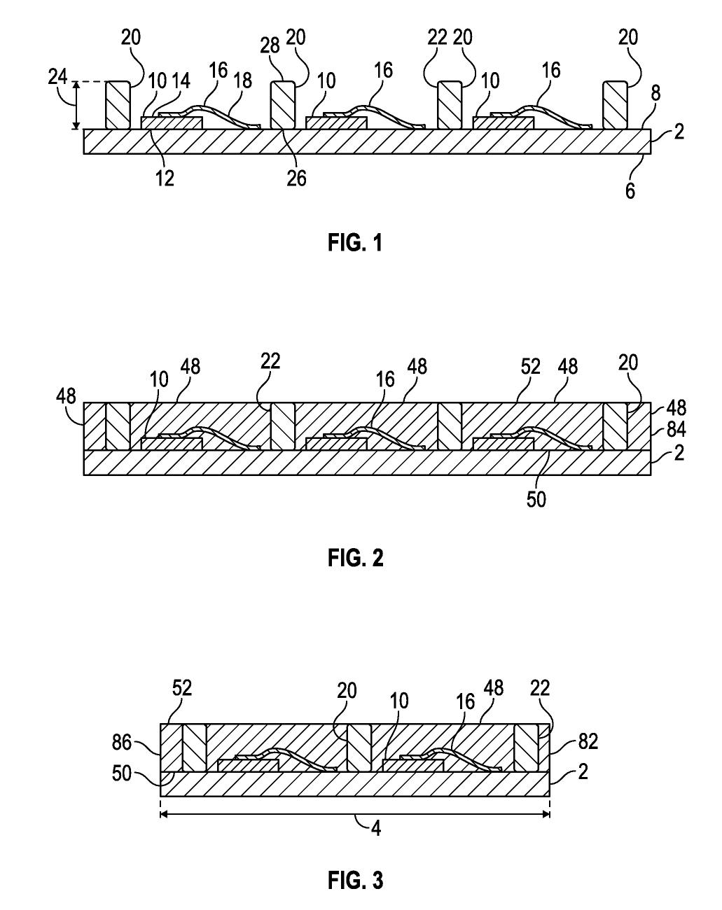

Referring now to FIGS. 1-3, various elements used in a method of forming a semiconductor package (package) 82 are shown. A substrate 2 includes a first surface 6 and a second surface 8 on an opposite side of the substrate 2 from the first surface 6. Substrate 2 may include any of a wide variety of substrate types including, by non-limiting example: a direct bonded copper (DBC) substrate; an active metal brazed (AMB) substrate; an insulated metal substrate; a ceramic substrate; and the like. Any type of substrate may be used so long as it includes connection traces on the second surface 8. In implementations where the substrate 2 is a DBC substrate, the DBC substrate may include a ceramic plate sandwiched between two copper layers, one of the layers forming connection traces on the second surface 8, or the DBC substrate may include a ceramic plate and only a single copper layer, the single copper layer forming connection traces on the second surface 8.

The connection traces are not shown in the drawings but are used to form electrical interconnections between the die 10, one or more electrical grounds, one or more power sources, one or more other die 10, and/or one or more other devices internal or external to package 82. Connection traces may be formed of copper, aluminum, gold, nickel, and/or other metals, alloys, and/or any other electrically conductive materials.

A plurality of die 10 are physically coupled to the second surface 8 and are electrically coupled with the connection traces. In the representative example shown each die 10 is coupled to the substrate 2 at a first surface 12 of the die 10. In various implementations, the first surface 12 of each die 10 is a back side of the die 10 which includes only electrical contacts (one or more) that are intended to be coupled to electrical ground and the second surface 14 of the die includes at least one electrical contact that is not intended only to be coupled to electrical ground. A pad or other electrical contact on the first surface 12 of each die may accordingly electrically couple the die to electrical ground through one or more of the connection traces of the second surface 8 of substrate 2 and an electrical connector 16 such as wirebond 18 couples one or more electrical contacts on the second surface 14 with one or more connection traces of the second surface of substrate 2. A conductive clip or other electrical connector could be used instead of a wirebond for electrical connector 16.

In view of the foregoing, the connection traces coupled with the second surface 14 through one or more electrical connectors 16 may couple electrical contacts on the second surface 14 with one or more power sources, with one or more other die 10, and/or with other components internal or external to package 82, while connection traces coupled with the first surface 12 may couple one or more electrical contacts on the first surface 12 with electrical ground. Naturally, this configuration could be reversed, and electrical contacts on the second surface 14 could be coupled to electrical ground while electrical contacts on the first surface 12 are coupled with one or more power sources, with one or more other die 10, and/or with other components internal or external to package 82. A different configuration may be used in which one or both of the first surface 12 and second surface 14 includes both electrical contacts that are intended to be coupled to electrical ground and electrical contacts that are intended to be coupled with one or more power sources, with one or more other die 10, and/or with other components internal or external to package 82. Finally, die 10 could, in various implementations, have electrical contacts on only one of either the first surface 12 or second surface 14. In implementations in which the die 10 has electrical contacts on only the second surface 14, one or more electrical connectors 16 may be used to couple the one or more electrical connectors to either or both of electrical ground and/or to one or more power sources, one or more other die, and/or other components internal or external to package 82 through the connection traces on the second surface 8 of substrate 2. In implementations in which the die 10 has electrical contacts on only the first surface 12, a flip chip configuration may be utilized in which the electrical connector 16 is omitted entirely and the connection traces of the second surface 8 of substrate 2 couple all of the electrical contacts of the die 10 with one or more electrical grounds, one or more power sources, one or more other die 10, and/or one or more other components internal or external to package 82. Similarly, each package 82 could include a variety of die configurations such as, by non-limiting example, one die 10 having a flip-chip configuration having only electrical contacts on first surface 12, another die 10 having electrical contacts on both the first surface 12 and second surface 14, and so forth.

In the representative examples shown in the drawings, each die 10 is a power semiconductor die such as, by non-limiting example, a power metal-oxide-semiconductor field-effect transistor (power MOSFET), an insulated gate bipolar transistor (IGBT) and/or the like. Accordingly, package 82 in the representative examples shown is a power integrated module (PIM) including one or more power MOSFETs and/or one or more IGBTs and/or one or more other power semiconductor die. In other implementations packages could be formed similar to package 82 which do not include power semiconductor die or which include one or more power semiconductor die in addition to one or more non-power semiconductor die.

Each of a plurality of sub-terminals 20 is physically coupled to the second surface 8 of the substrate 2 and is electrically coupled to one or more of the die 10 through one or more of the connection traces and/or one or more of the electrical connectors 16. In the representative example shown in the drawings each sub-terminal 20 is coupled on top of one or more of the connection traces and the one or more connection traces are in turn coupled to the die 10 through one or more electrical connectors 16 and/or through coupling to the first surface 12 of the die 10. Other configurations are possible—for example one or more sub-terminals 20 could be physically coupled to a location on the second surface 8 of the substrate 2 which does not include connection traces and the electrical coupling of the one or more sub-terminals 20 to one or more of the die 10 could be accomplished by directly attaching one or more electrical connectors 16 to the die 10 and to the sub-terminals 20 instead of indirectly coupling the die with sub-terminals through the connection traces.

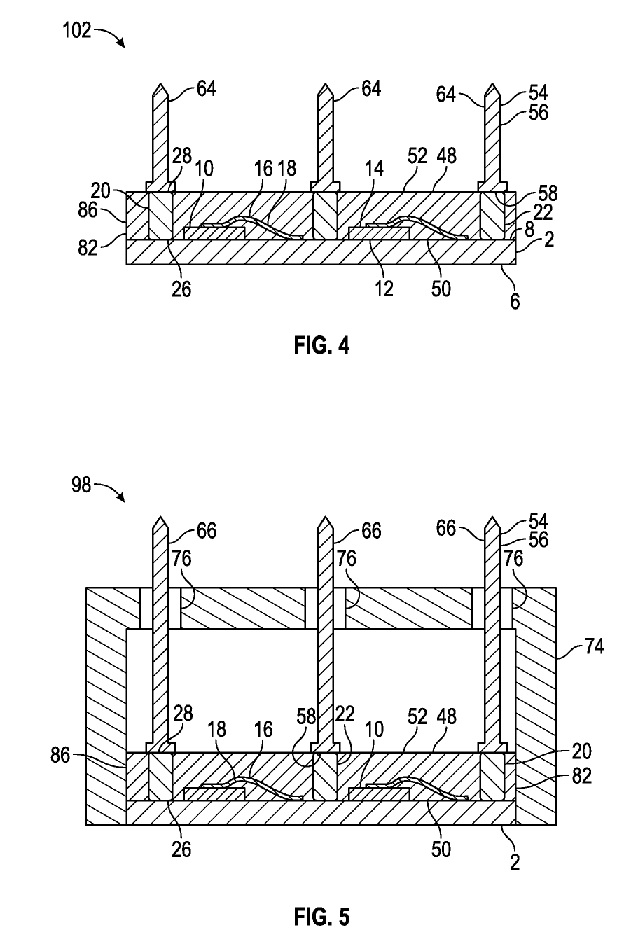

Each sub-terminal 20 is coupled to the substrate 2 at a first surface 26 of the sub-terminal 20 and has a second surface 28 on an opposite side of the sub-terminal 20 from the first surface 26. The sub-terminals are formed of an conductive (electrically, thermally, etc.) material such as a metal. In implementations each sub-terminal 20 is formed of copper with nickel and/or tin plating at the second surface 28. In implementations in which a tin or another low melting point metal is used, the plating may be reflowed to electrically and physically couple the sub-terminal 20 to one or more other elements such as a pin 54, as shown in FIGS. 4-7, the pin being configured to extend outside of a case as will be discussed elsewhere herein. The plating could also be used to couple the sub-terminals 20 to conductive traces of a second substrate 2 to form a stacked semiconductor package. For example, a second substrate 2 could include connection traces on both the first surface 6 and second surface 8 and the sub-terminals 20 of a first package 82 could be electrically coupled to the connection traces of the first surface 6 of the substrate 2 of a second package 82 to form a stacked semiconductor package. Whether or not low melting-point plating is used atop the sub-terminals, such coupling may be done with solder, a conductive adhesive, and so forth.

After substrate 2 has had a plurality of die 10 and sub-terminals 20 and, if appropriate, electrical connectors 16 coupled thereto, a mold compound 48 is used to encapsulate the die 10, the electrical connectors 16 (if present) and at least a portion of each sub-terminal 20. In various implementations, a majority of each sub-terminal 20 is encapsulated, and in the implementations shown in the drawings each sub-terminal 20 is encapsulated except for its second surface 28. Accordingly, the mold compound 48 in implementations may be coupled to the second surface 8 of the substrate 2 at a first surface 50 of the mold compound 48. A second surface 52 of the mold compound 48, on an opposite side of the mold compound 48 from the first surface 50, may be flush with the second surfaces 28 of the sub-terminals 20.

When the mold compound 48 is solidified and/or cured, a plurality of coupled semiconductor packages 84 are formed. The mold compound 48 in implementations could include one or more of the mold compounds sold under the following trade names by Sumitomo Bakelite Co., Ltd. of Tokyo, Japan (any of which may include the term “SUMITOMO” in the trade name as well): SUMIKON EME; G760; EME-G760; EME G770; EME-G770HJ; EME-G600; and/or SUMIKON EME-G600. The mold compound 48 in implementations could include one or more mold compounds sold under the following trade names by Hitachi Chemical Co., Ltd. of Tokyo, Japan (any of which may include the term “HITACHI” in the trade name as well): CEL-1620 HF16; CEL-1620 HF17; CEL-9200 HF10; CEL-9240 HF10; CEL-9200 HF9; CEL-1702 HF13; CEL-1802 HF19; CEL-9700 HF10; CEL-9750 HF10; CEL-9750 ZHF10; GE-100; GE-110; and/or CEL-9220. Other molding materials may be used and selected by those of ordinary skill using the principles disclosed herein.

The plurality of coupled semiconductor packages 84 are singulated to form a plurality of singulated semiconductor packages 86. A singulated semiconductor package 86 is shown in FIG. 3. Any type of singulation may be used such as, by non-limiting example: punch singulation, saw singulation, plasma etching, laser singulation, dicing by thinning, laser and mechanical hybrid methods, high pressure water jet singulation, and other processes capable of cutting the materials of coupled semiconductor packages 84. Various processes may be used to clean the singulated semiconductor packages 86 that are formed by the singulation process. The singulated semiconductor package 86 shown in FIG. 3 includes a plurality of die 10 and a plurality of sub-terminals 20. In other implementations a singulated semiconductor package 86 could include only a single die 10 and/or only a single sub-terminal 20. The sub-terminals 20 in the implementations shown are conductive pillars having a longest length 24 (see FIG. 7) that is perpendicular to, or substantially perpendicular to, a longest length 4 of the substrate 2 of the singulated semiconductor package 86. In other implementations other configurations could be used—for example the sub-terminal 20 could have a longest length that is parallel to, or substantially parallel to, the longest length 4 of the substrate 2 of the singulated semiconductor package 86, though forming the sub-terminals 20 so that their longest length is perpendicular (or substantially perpendicular) to the longest length of the substrate 2 of the singulated semiconductor package 86 may allow the sub-terminal 20 to take up less space on the second surface 8 and may more easily allow the sub-terminals 20 to be the uppermost item prior to encapsulation so that the second surfaces 28 may be exposed after encapsulation while other components, including die 10, any electrical connectors 16, and a majority of each sub-terminal 20, are encapsulated.

In implementations the singulated semiconductor package 86 may be coupled to a motherboard, printed circuit board (PCB), a heat sink or spreader or heat pipes, one or more power sources, one or more electrical grounds, and/or any other electrical components by attaching contacts of these elements with the sub-terminals 20 using solder, a conductive adhesive, and the like. In implementations further packaging of the singulated semiconductor package 86 may take place prior to making such connections. By non-limiting example, in the examples shown in FIGS. 4-6 different-sized and shaped pins 54 may be coupled to the sub-terminals 20 and/or a case 74, 78 may be used to further package singulated semiconductor package 86.

In the implementation shown in FIG. 4, and referring both to FIGS. 4 and 7, a short pin (pin) 64 is coupled to each sub-terminal 20 by soldering a first surface 58 of the pin 54 to the second surface 28 of the sub-terminal 20, to form a soldered pin (pin) 56, to form a power module 102. The short pins 64 may then be coupled to pin receivers to couple the pins 54, and therefore the sub-terminals 20 and die 10, to one or more of a power source, an electrical ground, one or more other electrical components, and the like. As indicated herein, the power module 102 may be a power integrated module (PIM). A heat sink or spreader or heat pipes may be coupled to the first surface 6 of the substrate 2 to draw heat away from the die 10. As detailed above, substrate 2 may be a double-sided DBC substrate, and thus the heat sink or spreader or heat pipes may be coupled to a copper sheet or layer on the first surface 6 of the substrate 2.

In the implementation shown in FIG. 5 a long pin (pin) 66 is coupled to each of the sub-terminals 20 by soldering in similar fashion to that described above for the short pins 64 and a case 74 is coupled to the singulated semiconductor package 86 to form a power module 98. The case 74 may be coupled to the singulated semiconductor package 86, by non-limiting example, by a press-fit, by a glue or other adhesive, by screws or other mechanical coupling mechanism, or the like. Thus the coupling may in implementations be permanent and in other implementations may be easily reversible without causing damage to the singulated semiconductor package 86 or any of its components so that the elements thereof could be inspected, repaired, replaced, etc. Case 74 includes a plurality of openings 76, one opening for each long pin 66, and the long pins 66 thus extend upwards from the sub-terminals 20 through the openings 76 in a sidewall of the case 74 and outside the case 74. The case 74 forms a cavity which encloses the singulated semiconductor package 86 except for the first surface 6 of the substrate 2. The long pins 66 may then be coupled to pin receivers to couple the pins 54, and therefore the sub-terminals 20 and die 10, to one or more of a power source, an electrical ground, one or more other electrical components, and the like, and as indicated above the singulated semiconductor package 86 may form a power semiconductor device such as a power integrated module (PIM). A heat sink or spreader or heat pipe may be coupled to the first surface 6 of the substrate 2 to draw heat away from the die 10 and, as detailed above, substrate 2 may be a double-sided DBC substrate and the heat sink/spreader/pipe may be coupled to a copper sheet/layer on the first surface 6 of substrate 2.

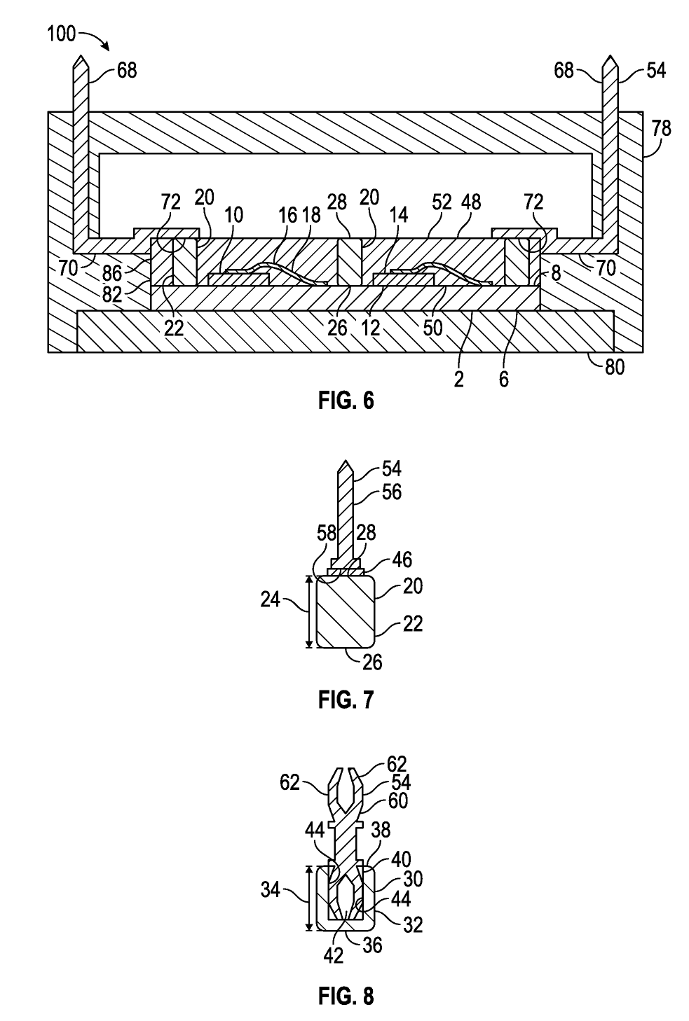

In the implementation shown in FIG. 6, a plurality of L-shaped pins (pins) 68 are coupled one or more of the sub-terminals 20 by soldering in similar fashion to that described above for the short pins 64 and a case 78 is coupled to the singulated semiconductor package 86. The case 78 may be coupled to the singulated semiconductor package 86, by non-limiting example, by a press-fit, by a glue or other adhesive, by screws or other mechanical coupling mechanism, or the like. Thus the coupling may in implementations be permanent and in other implementations may be easily reversible without causing damage to the singulated semiconductor package 86 or any of its components so that the elements thereof could be inspected, repaired, replaced, etc. In the implementation shown the L-shaped pins 68 are integrally formed within the case 78. By non-limiting example, in implementations the case 78 is formed of a thermoplastic or thermosoftening plastic that is melted and then formed around the L-shaped pins 68 and then allowed to cool and solidify so that the L-shaped pins 68 are integrated within the sidewalls of the case 78. In other implementations the case 78 could be formed of a thermosetting polymer and the L-shaped pins 68 may be integrally formed within the sidewalls of the case 78 in similar fashion.

Each L-shaped pin 68 includes a first surface 72 which may be couple to a second surface 28 of a sub-terminal 20 and a side member 70 which extends the pin 54 to a sidewall of the case 78 where the pin 54 is encased within the sidewall. Each L-shaped pin 68 extends upwards through the sidewalls of the case 78 and outside the case 78. A base plate 80 is coupled to the case 78 and may be permanently or temporarily coupled thereto using, by non-limiting example, a friction fit, a glue or other adhesive, screws, and the like. Base plate 80 is also coupled to the first surface 6 of substrate 2 and in implementations is formed of a metal or other material with high thermal conductivity and thus acts as a heat sink or spreader or heat pipe to draw heat away from the die 10 through the substrate 2 and base plate 80. As detailed above, substrate 2 may be a double-sided DBC substrate and the base plate 80 may be coupled to a copper sheet/layer on the first surface 6 of substrate 2. The case 78 and base plate 80 together form a cavity which encloses the singulated semiconductor package 86. In implementations the singulated semiconductor package 86 is completely enclosed within the case 78 and base plate 80. The L-shaped pins 68 may be coupled to pin receivers to couple the pins 54, and therefore the sub-terminals 20 and die 10, to one or more of a power source, an electrical ground, one or more other electrical components, and the like, and as indicated above the singulated semiconductor package 86 may include a power semiconductor device such as a power integrated module (PIM). The case 78, L-shaped pins 68, base plate 80, and singulated semiconductor package 86 of FIG. 6 together form power module 100.

In some implementations of packages and/or power modules such as those shown in FIGS. 4-6 not every sub-terminal 20 will be coupled to a pin 54. For example, referring to the package shown in FIG. 6, three sub-terminals 20 are shown, with the leftmost sub-terminal 20 coupled to a first L-shaped pin 68, the rightmost sub-terminal 20 coupled to a second L-shaped pin 68, and a central sub-terminal 20 not coupled to any pin 54. In various implementations, the sub-terminals 20 may add some stability and rigidity to singulated semiconductor package 86 and thus, even when not used as an electrical connector, sub-terminals 20 may be placed throughout the singulated semiconductor package 86 such as at regular intervals. In some implementations of packages and/or power modules similar to those shown in FIGS. 4 and 5 not every sub-terminal 20 will be coupled to a pin 54. In some implementations of packages and/or power modules elements of the packages shown in FIGS. 5 and 6 may be combined—for example some pins 54 may be integrally formed within a sidewall of a case while other pins may extend through an opening in a top of the case.

FIG. 7 shows an implementation of a pin 54 coupled to a sub-terminal 20. The sub-terminal 20 shown is a conductive pillar 22 having a longest length 24 that is vertical in the figure or, in other words, is parallel with, or substantially parallel with, the pin 54, and also perpendicular to, or substantially perpendicular to, a longest length 4 of the substrate 2 to which the sub-terminal 20 will be coupled. The specific pin 54 shown is a soldered pin 56 which has a first surface 58 at its lower extremity that is soldered to a second surface 28 (which is an upper surface) of the sub-terminal 20 using a solder 46. The sub-terminal 20 has a first surface 26 opposite the second surface 28 which is configured to be coupled to the second surface 8 of the substrate 2.

The relative sizes and dimensions of the sub-terminals 20 and pins 54 may be altered. Thus in FIG. 7 the pin 54 is a short pin 64 and the widest portion of the pin 54, at a base of the pin 54, is not as wide as the width of the sub-terminal 20. In the implementations of pins 54 and sub-terminals 20 shown in FIGS. 4 and 5, however, the short pins 64 and long pins 66 are each shown as having a base width that is greater than a greatest width of the sub-terminals 20. As indicated above, sub-terminal 20 could have different configurations in which its longest length is parallel with, or substantially parallel with, the longest length 4 of the substrate 2 when coupled thereto, though having the configuration shown in FIG. 7 may have the advantages described elsewhere herein.

Referring now to FIG. 8, in implementations a sub-terminal 30 may be used with singulated semiconductor package 86 and any of the packages and/or power modules described herein including all those shown in FIGS. 1-6. Sub-terminal 30 includes a conductive pillar 32 having an opening 40 providing access to a cavity 42 defined by the inner sidewalls 44 of the conductive pillar 32. A first surface 36 at a bottom of the sub-terminal 30 is configured to be coupled to the second surface 8 of substrate 2 and a second surface 38 is located on a side of the sub-terminal 30 opposite the first surface 36. The sub-terminal 30 has a longest length 34 that is perpendicular or substantially perpendicular to a longest length 4 of the substrate 2 when coupled thereto. The longest length 34 is also parallel with, or substantially parallel with, a pin 54 which is coupled thereto. Similar to that indicated above with respect to sub-terminal 20, sub-terminal 30 could have different configurations in which its longest length is parallel with, or substantially parallel with, the longest length 4 of the substrate 2 when coupled thereto, though having the configuration shown in FIG. 8 may have the advantages described herein with respect to sub-terminal 20.

Sub-terminal 30 is configured to receive a pin 54 which is a press-fit pin (pin) 60 having a plurality of friction members 62. The friction members 62 are configured to be pressed up against the inner sidewalls 44 when the press-fit pin 60 is inserted into the cavity 42 to provide a friction fit between the inner sidewalls 44 and the friction members 62, thus causing the press-fit pin 60 to tend to stay in place, though in implementations the press-fit pin 60 may be removed therefrom with manual force alone.

Although all of the sub-terminals shown and described herein are coupled to pins 54, in implementations a sub-terminal could integrally include a pin so that a pin does not need to be soldered, press-fit, or otherwise attached to the sub-terminal thereafter, but is integrally included with the sub-terminal to begin with.

Each sub-terminal described herein could be coupled to one die 10 or, in implementations, one or more sub-terminals could be coupled with multiple die 10. In implementations each sub-terminal could be coupled with more than one die 10. In implementations there may be one or more sub-terminals that is coupled to every die 10 within a package—for instance a sub-terminal that is coupled to a power source may in implementations be electrically coupled with every die 10 of the package, though in implementations the sub-terminal may also be coupled with only some or only one of the die 10 of the package.

All of the electrical connections described herein, such as coupling the sub-terminals 20, 30 to the second surface 8 of the substrate 2 (and/or to connection traces thereon), coupling of the die 10 to the second surface 8 of the substrate 2 (and/or to connection traces thereon), coupling the electrical connector 16 to the die 10 and to the second surface 8 of the substrate (and/or to connection traces thereon), coupling the pins 54 to the second surface 28 of the sub-terminals 20, 30, and the like, may be done using any connection method allowing a physical and electrical coupling such as, by non-limiting example, using a conductive solder, using a conductive adhesive, using a press-fit, and using any other connection or coupling mechanism whereby the two elements are physically and electrically coupled together.

As has been described herein, the encapsulation step in implementations takes place prior to the singulation step. In conventional power modules such as PIMs the encapsulation compound is a silicone potting compound and is not applied until after singulation has already taken place. By non-limiting example, referring to FIGS. 5 and 6, in implementations cases 74, 78 include holes in an upper portion that are configured to allow a potting compound to be dispensed therethrough to encapsulate the elements including the die 10, portions of the sub-terminals 20, the electrical connectors 16, and the like. The sidewalls of the cases 74, 78 prevent the potting compound from spilling out and otherwise generally confine the potting compound to within the cavities formed by cases 74, 78. While silicone potting compound could be applied after the cases 74, 78 are put in place, in implementations the use of a different type of a mold compound 48—such as a thermoplastic, thermosoftening plastic, thermosetting plastic (such as with resin transfer molding), or another other polymer material—allows the mold compound 48 to be applied to the entire array of coupled semiconductor packages 84 prior to singulation and thus reduces time and cost of the encapsulation step. The material costs for silicone potting compound are also relatively expensive compared with other mold compounds, and thus the removal of the need for silicone potting may reduce the overall cost of the packages and/or power modules shown herein.

Thus, in implementations a conventional process flow for forming a PIM package may include the following steps in the following order: a die bond process to bond the die to a substrate (such as a DBC substrate); a wirebond process to electrically couple electrical connectors of the die with conductive traces of the substrate (though, for flip chip and similar packages, this step may be omitted or in other implementations clips or the like may be used instead of wirebonds); singulation of the substrate; attachment of leads (similar in some ways to the pins disclosed herein); attachment of a case and enclosure of the elements of the package within a cavity of the case, and; silicone potting. In implementations a process flow for forming a PIM or other semiconductor package according to the elements and methods disclosed herein includes the same steps in the same order except that the step of silicone potting is not done and a step of panel molding, such as using transfer molding (such as resin transfer molding), compression molding, injection molding, plunger molding, reaction injection molding (RIM), open molding, or the like, is done immediately prior to the singulation step. Thus, in implementations, the conventional silicone potting step is replaced with map molding using transfer molding (such as resin transfer molding) on a DBC panel for PIM packages and/or power modules.

In implementations a power module may have pins 54/68 extending outside of the case 78 only along an outer perimeter, as shown by the power module 100 of FIGS. 6 and 10. It may also be seen from FIG. 10 that in implementations a power module 100 includes couplers 94 and couplers 96, which in the drawings are screw holes configured to receive screws. One set of these couplers may be used, for example, to couple the case 78 to the base plate 80, such as with screws, while the other set may be used to couple the case 78 to a motherboard, printed circuit board (PCB), heat sink or heat spreader or heat pipe, or the like, also with screws. Other coupling mechanisms could be used.

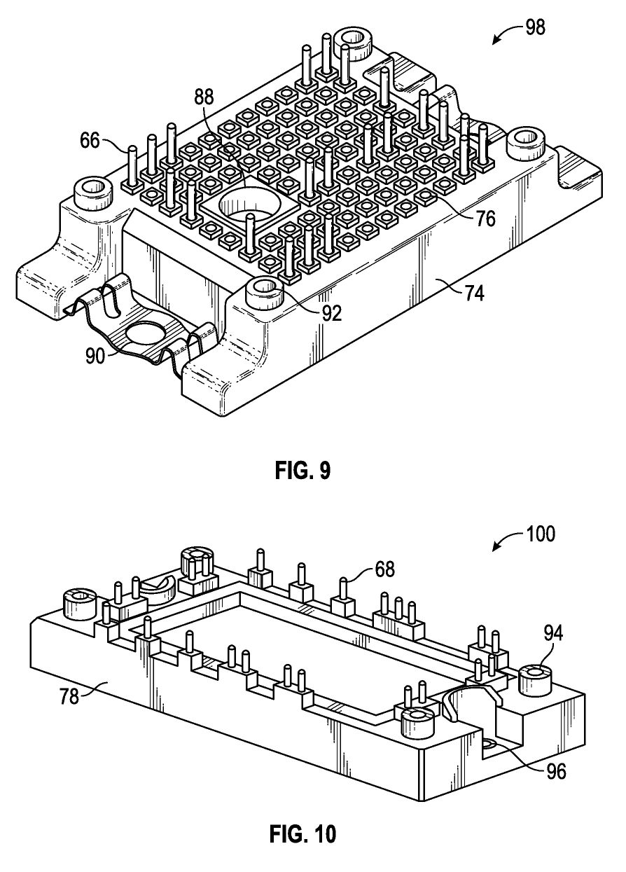

In other implementations a power module may have pins 54/66 extending outside the case 74 in an array and not only along an outer perimeter of the case 74, as shown by the power module 98 of FIGS. 5 and 9. It may also be seen from FIG. 9 that in implementations a power module 98 includes couplers 90 and couplers 92, which in the drawings are screw holes configured to receive screws. One set of these couplers may be used, for example, to couple the case 74 to a motherboard, printed circuit board (PCB), electrical ground, heat sink or heat spreader or heat pipe, or the like, such as with screws, while the other set may be used to couple the case 74 to another of these elements, also with screws. Other coupling mechanisms could be used. In FIG. 9 case 74 is seen with an opening 88 that is conventionally used to deposit silicone potting material. As discussed herein, in implementations silicone potting is not used and transfer molding (such as resin transfer molding) is used to apply a mold compound to the coupled semiconductor packages 84 prior to singulation instead of using silicone potting after singulation and after placing the singulated semiconductor package 86 within a cavity of the case 74.

In implementations the sub-terminals 20, 30 may be cylindrical, though in other implementations they could be shaped as cuboids (such as rectangular cuboids) and, in other implementations they could have any other regular or irregular closed shape. Thus the first surface 26/36 and/or second surface 28/38 could have the shape of a circle, an oval, an ellipse, a square, a rectangle, a triangle, any n-sided polygon wherein “n” is any integer, and any other regular or irregular closed shape.

In implementations each sub-terminal 20, 30 as described herein may be formed of a solderable material such as, by non-limiting example, copper with nickel and/or tin plating at the first surface 26/36 and/or second surface 28/38. The placement of the sub-terminals 20, 30 may be done by a chip mounter, a pick and place tool, and the like. In implementations the singulation of the coupled semiconductor packages 84 to form singulated semiconductor packages 86 may be done by dicing.

In implementations the sub-terminals 20, 30 serve as spacers between the substrate 2 and the pins 54.

In places where the description above refers to particular implementations of semiconductor packages with sub-terminals and related methods and implementing components, sub-components, methods and sub-methods, it should be readily apparent that a number of modifications may be made without departing from the spirit thereof and that these implementations, implementing components, sub-components, methods and sub-methods may be applied to other semiconductor packages with sub-terminals and related methods.

What is claimed is:

1. A method of forming a semiconductor package, comprising:
coupling each of a first surface of a plurality of die with a second surface of a substrate, the substrate comprising a first surface on a side of the substrate opposing the second surface of the substrate, each of the plurality of die having a second surface on an opposing side of the die from the first surface of the die;
coupling each first surface of a plurality of electrically conductive sub-terminals to the second surface of the substrate, each sub-terminal comprising a second surface on an opposing side of the sub-terminal from the first surface of the sub-terminal;
encapsulating each of the plurality of die and a majority of each sub-terminal in a mold compound to form a plurality of coupled semiconductor packages;
coupling a pin to one of the sub-terminals through one of soldering and a friction fit;
after encapsulating, singulating the plurality of coupled semiconductor packages to form a plurality of singulated semiconductor packages; and
coupling a case over the second surface of the substrate, the pin extending through an opening in the case.

2. The method of claim 1, wherein the mold compound is coupled to the second surface of the substrate at a first surface of the mold compound, and wherein a second surface of the mold compound, on an opposing side of the mold compound from the first surface of the mold compound, is flush with the second surface of each sub-terminal.

3. The method of claim 1, wherein each sub-terminal is electrically coupled, through an electrical connector, with an electrical contact of one of the die, the electrical contact located on one of the first surface of the die and the second surface of the die.

4. The method of claim 1, wherein each sub-terminal comprises a pillar and wherein each pillar comprises a longest length that is perpendicular to a longest length of the substrate.

5. The method of claim 1, wherein encapsulating each die and a majority of each sub-terminal in the mold compound comprises resin transfer molding and wherein the mold compound does not comprise silicon.

6. The method of claim 1, wherein the case does not include an opening configured for application of a potting compound therein.

7. The method of claim 1, further comprising not applying any potting compound into the case after coupling the case over the second surface of the substrate.

8. A method of forming a semiconductor device package, comprising:
coupling a plurality of die with a substrate, each die coupled to the substrate at a first surface of the die and at a second surface of the substrate, the substrate comprising a first surface on a side of the substrate opposing the second surface of the substrate, each of the plurality of die having a second surface on an opposing side of the die from the first surface of the die;
coupling each first surface of a plurality of conductive pillars to the second surface of the substrate, each conductive pillar electrically coupled with one of the plurality of die, each conductive pillar comprising a second surface on a side of the conductive pillar opposing the first surface of the conductive pillar;
encapsulating each of the plurality of die and a portion of each conductive pillar in a mold compound, forming a plurality of coupled semiconductor packages,
after encapsulating, singulating the plurality of coupled semiconductor packages to form a plurality of singulated semiconductor packages;
coupling a pin to one of the conductive pillars; and
coupling a case over the second surface of the substrate while extending the pin through an opening in the case.

9. The method of claim 8, wherein the pin is coupled to one of the singulated semiconductor packages and wherein a longest length of the pin is substantially perpendicular to a longest length of the singulated semiconductor package to which the pin is coupled.

10. The method of claim 8, wherein the mold compound is coupled to the second surface of the substrate at a first surface of the mold compound and wherein a second surface of the mold compound, on an opposing side of the mold compound from the first surface of the mold compound, is flush with the second surface of each conductive pillar.

11. The method of claim 9, wherein encapsulating each of the die and a portion of each conductive pillar in a mold compound comprises resin transfer molding and wherein the mold compound does not comprise silicon.

12. The method of claim 8, wherein each conductive pillar is electrically coupled, through an electrical connector, with an electrical contact of one of the die, the electrical contact located on one of the first surface of the die and the second surface of the die.

13. The method of claim 8, wherein the case does not include an opening configured for application of a potting compound therein.

14. The method of claim 8, further comprising not applying any potting compound into the case after coupling the case over the second surface of the substrate.

15. A method of forming a semiconductor device package, comprising:
coupling a plurality of die with a substrate, each die coupled to the substrate at a first surface of the die and at a second surface of the substrate, the substrate comprising a first surface on a side of the substrate opposing the second surface of the substrate, each of the plurality of die having a second surface on an opposing side of the die from the first surface of the die;
coupling each first surface of a plurality of conductive pillars to the second surface of the substrate, each conductive pillar electrically coupled with one of the plurality of die, each conductive pillar comprising a second surface on a side of the conductive pillar opposing the first surface of the conductive pillar;
encapsulating each of the plurality of die and a portion of each conductive pillar in a mold compound, forming a plurality of coupled semiconductor packages,
after encapsulating, singulating the plurality of coupled semiconductor packages to form a plurality of singulated semiconductor packages;
coupling an L-shaped pin to one of the conductive pillars; and
integrally forming a case over the L-shaped pin.

16. The method of claim 15, wherein integrally forming the case over the L-shaped in further comprising coupling the case over the second surface of the substrate.

17. The method of claim 16, further comprising not applying any potting compound into the case after coupling the case over the second surface of the substrate.

18. The method of claim 15, wherein the case does not include an opening configured for application of a potting compound therein.

19. The method of claim 15, wherein encapsulating each of the die and a portion of each conductive pillar in a mold compound comprises resin transfer molding and wherein the mold compound does not comprise silicon.

20. The method of claim 15, wherein each conductive pillar is electrically coupled, through an electrical connector, with an electrical contact of one of the die, the electrical contact located on one of the first surface of the die and the second surface of the die.
